(19) United States
(12) Patent Application Publication
(10) Pub. No.: US 2012/0103258 A1
(43) Pub. Date: May 3, 2012

(54) Chemical Vapor Deposition Apparatus and Cooling Block Thereof

(75) Inventors: Chengming He, Guangdong (CN); Chun-ming Hung, Guangdong (CN)

(73) Assignee: Shenzhen China Star Optoelectronics Technology Co., Ltd., Shenzhen (CN)

(21) Appl. No.: 12/997,019

(22) PCT Filed: Nov. 24, 2010
(86) PCT No.: PCT/CN10/79036

§ 371 Date: Dec. 9, 2010

(30) Foreign Application Priority Data
Nov. 2, 2010 (CN) 201010530714.5

(51) Int. Cl. C23C 16/50

(52) U.S. Cl. 118/723 R

(57) ABSTRACT

The present invention provides a chemical vapor deposition apparatus and a cooling block thereof. The chemical vapor deposition apparatus comprises a process chamber; at least one clean gas channel connected between the process chamber and a remote plasma source; and an anti-fluoride material layer formed in the clean gas channel. The clean gas channel can be formed in a block body of the cooling block. The present invention can enhance the cleaniness of the process chamber.

### FIELD OF THE INVENTION

The present invention relates to a chemical vapor deposition (CVD) apparatus and a cooling block thereof, and more particularly to a chemical vapor deposition apparatus and a cooling block thereof capable of chamber self-cleaning.

### BACKGROUND OF THE INVENTION

Chemical vapor deposition is a chemical process used to produce high-purity, high-performance solid materials. In general, a CVD apparatus can perform a chamber self-cleaning to improve the cleaniness in a process chamber thereof. At this time, a clean gas, such as NF₃ gas, can dissociate into fluorine (F) ions by means of a remote plasma source (RPS), and the fluorine ions can be transported into the process chamber through a cooling block and gas pipes for cleaning the process chamber.

However, before the fluorine ions are transported into the process chamber, since the cooling block and the gas pipes are made of a metal material, such as aluminum, a portion of the fluorine ions may react with the metal material of the cooling block or the gas pipes and can not enter the process chamber. For example, the fluorine ions may react with aluminum to form aluminum fluoride. Therefore, the fluorine ions entering the process chamber may be not sufficient to perform the chamber self-cleaning, i.e. the clean rate may be not sufficient, thereby deteriorating the cleaniness of the process chamber.

As a result, it is necessary to provide a chemical vapor deposition apparatus and a cooling block thereof to solve the problems existing in the conventional technologies, as described above.

### SUMMARY OF THE INVENTION

A primary object of the present invention is to provide a chemical vapor deposition apparatus, and the chemical vapor deposition apparatus comprises: a process chamber; at least one clean gas channel connected between the process chamber and a remote plasma source; and an anti-fluoride material layer formed in the clean gas channel.

Another object of the present invention is to provide a chemical vapor deposition apparatus, and the chemical vapor deposition apparatus comprises: a process chamber; a first cooling block connected to a remote plasma source; a second cooling block connected to the process chamber; a gas pipe connected between the first cooling block and the second cooling block; at least one clean gas channel connected between the process chamber and the remote plasma source, wherein the clean gas channel is formed in at least one of the first cooling block, the second cooling block and the gas pipe; and an anti-fluoride material layer formed in the clean gas channel.

A further object of the present invention is to provide a cooling block of a chemical vapor deposition apparatus, and the cooling block comprises: a block body; at least one clean gas channel formed in the block body and connected between a process chamber of the chemical vapor deposition apparatus and a remote plasma source; and an anti-fluoride material layer formed in the clean gas channel.

In one embodiment of the present invention, the chemical vapor deposition apparatus further comprises a first cooling block, a gas pipe and a second cooling block, and the first cooling block is connected to the remote plasma source, and the gas pipe is connected between the first cooling block and the second cooling block, and the second cooling block is connected to the process chamber.

In one embodiment of the present invention, the clean gas channel is formed in at least one of the first cooling block, the second cooling block and the gas pipe.

In one embodiment of the present invention, the anti-fluoride material layer is a coating layer.

In one embodiment of the present invention, the anti-fluoride material layer is formed by a pipe.

In one embodiment of the present invention, the material of the anti-fluoride material layer is Teflon.

In one embodiment of the present invention, the anti-fluoride material layer is formed on the whole inner sidewall of the clean gas channel.

In one embodiment of the present invention, the anti-fluoride material layer is formed on the partial inner sidewall of the clean gas channel.

In one embodiment of the present invention, the chemical vapor deposition apparatus further comprises an anti-fluoride material pipe which is formed as one piece of an anti-fluoride material, and the clean gas channel is formed in the anti-fluoride material pipe, thereby forming the anti-fluoride material layer in the clean gas channel.

In one embodiment of the present invention, the anti-fluoride material layer is selected from a material except metallic oxide.

The CVD apparatus of the present invention can prevent the fluorine ions from the fluoridation reactions before entering the process chamber by means of the anti-fluoride material layer in the clean gas channel, thereby enhancing the amount of the fluorine ions entering the process chamber and the cleaniness thereof.

The structure and the technical means adopted by the present invention to achieve the above and other objects can be best understood by referring to the following detailed description of the preferred embodiments and the accompanying drawings.

### DESCRIPTION OF THE DRAWINGS

FIG. 1 is a schematic diagram showing a CVD apparatus according to a first embodiment of the present invention;

FIG. 2A and FIG. 2B are cross-sectional views showing the CVD apparatus according to the first embodiment of the present invention;

FIG. 3 is a schematic diagram showing a CVD apparatus according to a second embodiment of the present invention; and

FIG. 4 is a schematic diagram showing a CVD apparatus according to a third embodiment of the present invention.

### DETAILED DESCRIPTION OF THE PREFERRED EMBODIMENTS

The following embodiments are referring to the accompanying drawings for exemplifying specific implementable embodiments of the present invention. Furthermore, directional terms described by the present invention, such as upper, lower, front, back, left, right, inner, outer, side and etc., are only directions by referring to the accompanying drawings, and thus the used directional terms are used to describe and understand the present invention, but the present invention is not limited thereto.

In the drawings, structure-like elements are labeled with like reference numerals.

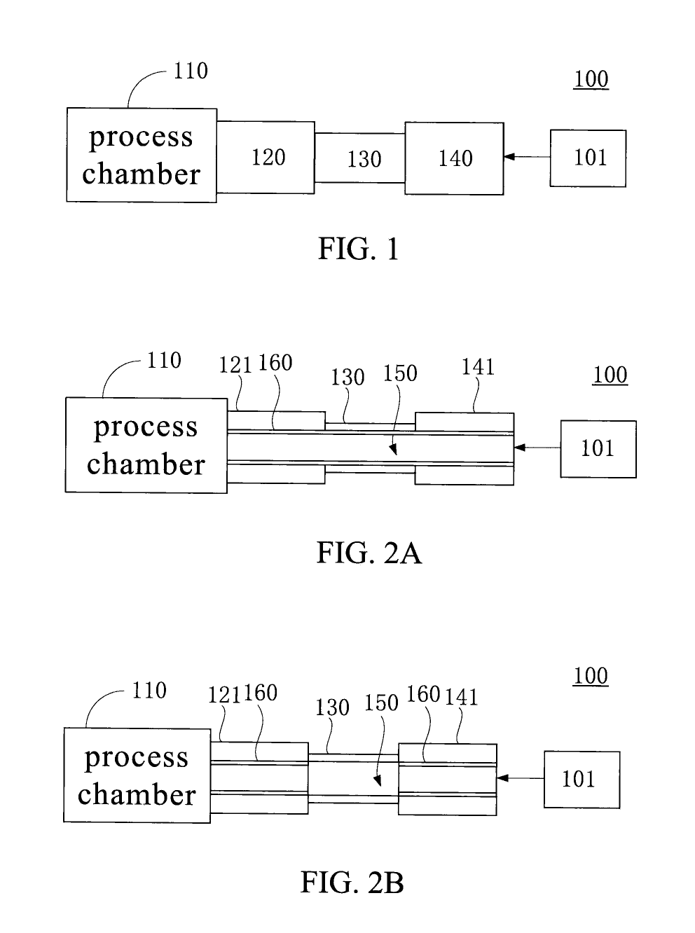

Referring to FIG. 1, a schematic diagram showing a CVD apparatus according to a first embodiment of the present invention is illustrated. The CVD apparatus 100 of the present embodiment may be configured to deposit materials on a substrate. For example, a film can be formed on a wafer or a glass substrate by the CVD apparatus 100. The CVD apparatus 100 of the present embodiment can implement a chamber self-cleaning by using a RPS 101 to provide a fluorine ion gas. The RPS 101 can be disposed in the CVD apparatus 100. Alternatively, the RPS 101 may also be disposed external to the CVD apparatus 100.

Referring to FIG. 1, FIG. 2A and FIG. 2B, FIG. 2A and FIG. 2B are cross-sectional views showing the CVD apparatus according to the first embodiment of the present invention. The CVD apparatus 100 of the present embodiment may comprise a process chamber 110, a first cooling block 120, a gas pipe 130, a second cooling block 140, at least one clean gas channel 150 and an anti-fluoride material layer 160. The process chamber 110 is used for a deposition process, wherein the substrate (not shown) waited for deposition can be placed in the process chamber 110, and a material can be deposited thereon. The first cooling block 120 and the second cooling block 140 can be used for cooling. The first cooling block 120 may be connected to the RPS 101. The gas pipe 130 may be a metal gas pipe connected between the first cooling block 120 and the second cooling block 140 so as to allow at least one gas passing. The second cooling block 140 may be connected to the process chamber 110. In this case, the material of a block body 121 of the first cooling block 120 and/or a block body 141 of the second cooling block 140 may be metal, such as aluminum.

Referring to FIG. 1, FIG. 2A and FIG. 2B again, in the present embodiment, the clean gas channel 150 is formed in the block body 121 of the first cooling block 120, the gas pipe 130 and/or the block body 141 of the second cooling block 140. The clean gas channel 150 is connected between the process chamber 110 and the RPS 101 for providing the fluorine ion gas from the RPS 101 to the process chamber 110. Therefore, the fluorine ion gas can be provided from the RPS 101 to pass through the clean gas channel 150, and then enter the process chamber 110 for the chamber self-cleaning, thereby improving the cleaniness of the process chamber 110.

Referring to FIG. 1, FIG. 2A and FIG. 2B again, the anti-fluoride material layer 160 of the present embodiment is formed on the inner sidewall of the clean gas channel 150 for preventing fluoridation reactions of the fluorine ions before entering the process chamber 110. Therefore, the amount of the fluorine ions entering the process chamber 110 can be enhanced by the anti-fluoride material layer 160. In this embodiment, the anti-fluoride material layer 160 may be a coating layer formed on the inner sidewall of the clean gas channel 150 by using an anti-fluoride material. The anti-fluoride material may be Teflon or other anti-fluoride materials which can not react with the fluorine ions. It is worth mentioning that, for enhancing the anti-fluoride function, the anti-fluoride material layer 160 is preferably made of the anti-fluoride material except metallic oxide, since the metallic oxide (such as aluminum oxide) is susceptible to peel and thus lose the anti-fluoride function.

Referring to FIG. 2A again, the anti-fluoride material layer 160 of the present embodiment can be formed on the whole inner sidewall of the clean gas channel 150. Alternatively, the anti-fluoride material layer 160 may also be formed on the partial inner sidewall of the clean gas channel 150. For example, referring to FIG. 2B, the anti-fluoride material layer 160 can be merely formed in the first cooling block 120 and the second cooling block 140. The anti-fluoride material layer 160 can cover at least a material (such as aluminum) which is susceptible to react with the fluorine ions, thereby forming a separation so as to prevent the fluorine ions from the fluoridation reactions before entering the process chamber 110. For example, when the material of the block body 121 of the first cooling block 120 and the block body 141 of the second cooling block 140 is aluminum, the anti-fluoride material layer 160 can be formed in at least the block body 121 of the first cooling block 120 and the block body 141 of the second cooling block 140 for preventing the fluoridation reactions.

When performing the self-cleaning of the CVD apparatus 100 of the present invention, a clean gas (such as NF₃, C₂F₆, CF₄) can dissociate into fluorine ions by means of the RPS 101. The fluorine ions can be provided into the process chamber 110 through the clean gas channel 150, and then react with the residues (such as SiNₓ, Si, SiO₂) in the process chamber 110, and the reactant thereof can be exhausted out the process chamber 110, thereby achieving the chamber self-cleaning. When the fluorine ions pass through the clean gas channel 150, the fluoridation reactions of the fluorine ions before entering the process chamber 110 can be prevented by the anti-fluoride material layer 160. Therefore, the amount of the fluorine ions entering the process chamber 110 can be enhanced so as to solve the problem that the clean rate is insufficient resulting from the insufficient fluorine ions in the process chamber 110. In this way, the CVD apparatus 100 of the present embodiment can enhance the cleaniness of the process chamber 110.

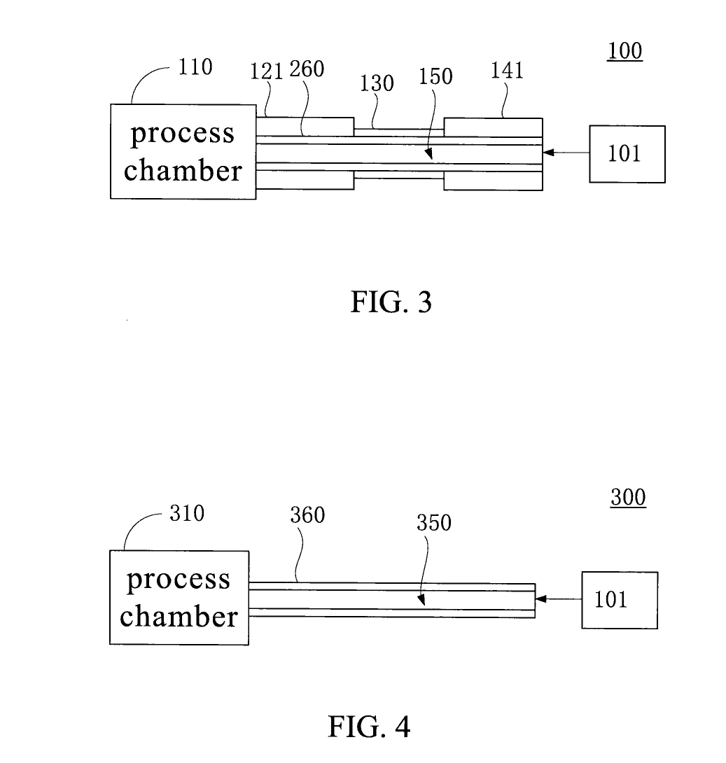

Referring to FIG. 3, a schematic diagram showing a CVD apparatus according to a second embodiment of the present invention is illustrated. Only the difference between the embodiment and the first embodiment will be described hereinafter, and thus the similar portions there-between will be not stated in detail herein. In comparison with the first embodiment, the anti-fluoride material layer 260 of the second embodiment is formed by a pipe which is preferably made of the anti-fluoride material as one piece. This pipe can be inserted in the clean gas channel 150 (the first cooling block 120, the gas pipe 130 and/or the second cooling block 140), thereby forming the anti-fluoride material layer 260 in the clean gas channel 150 to enhance the amount of the fluorine ions entering the process chamber 110.

Referring to FIG. 4, a schematic diagram showing a CVD apparatus according to a third embodiment of the present invention is illustrated. Only the difference between the embodiment and the first embodiment will be described hereinafter, and thus the similar portions there-between will be not stated in detail herein. In comparison with the first embodiment, the CVD apparatus 300 of the second embodiment may comprise a process chamber 310, at least one clean gas channel 350 and an anti-fluoride material pipe 360. The anti-fluoride material pipe 360 is preferably a pipe body which is formed as one piece of the anti-fluoride material and connected between the process chamber 310 and the RPS 101. The clean gas channel 350 is formed in the anti-fluoride material pipe 360, thereby naturally forming the anti-fluoride material layer in the clean gas channel 350 to enhance the amount of the fluorine ions entering the process chamber 310.

As described above, the CVD apparatus of the present invention can prevent the fluorine ions from the fluoridation reactions before entering the process chamber by means of the anti-fluoride material layer in the clean gas channel, thereby enhancing the amount of the fluorine ions entering the process chamber and the cleaniness thereof.

The present invention has been described with a preferred embodiment thereof and it is understood that many changes and modifications to the described embodiment can be carried out without departing from the scope and the spirit of the invention that is intended to be limited only by the appended claims.

1. A chemical vapor deposition apparatus, characterized in that: the chemical vapor deposition apparatus comprises:
a process chamber;
a first cooling block connected to a remote plasma source;
a second cooling block connected to the process chamber;
a gas pipe connected between the first cooling block and the second cooling block;
at least one clean gas channel connected between the process chamber and the remote plasma source, wherein the clean gas channel is formed in at least one of the first cooling block, the second cooling block and the gas pipe; and
an anti-fluoride material layer formed in the clean gas channel.

2. A chemical vapor deposition apparatus, characterized in that: the chemical vapor deposition apparatus comprises:
a process chamber;
at least one clean gas channel connected between the process chamber and a remote plasma source; and
an anti-fluoride material layer formed in the clean gas channel.

3. The chemical vapor deposition apparatus according to claim 2, characterized in that: the chemical vapor deposition apparatus further comprises a first cooling block, a gas pipe and a second cooling block, and the first cooling block is connected to the remote plasma source, and the gas pipe is connected between the first cooling block and the second cooling block, and the second cooling block is connected to the process chamber.

4. The chemical vapor deposition apparatus according to claim 3, characterized in that: the clean gas channel is formed in at least one of the first cooling block, the second cooling block and the gas pipe.

5. The chemical vapor deposition apparatus according to claim 2, characterized in that: the anti-fluoride material layer is a coating layer.

6. The chemical vapor deposition apparatus according to claim 2, characterized in that: the anti-fluoride material layer is formed by a pipe.

7. The chemical vapor deposition apparatus according to claim 2, characterized in that: the material of the anti-fluoride material layer is Teflon.

8. The chemical vapor deposition apparatus according to claim 2, characterized in that: the anti-fluoride material layer is formed on the whole inner sidewall of the clean gas channel.

9. The chemical vapor deposition apparatus according to claim 2, characterized in that: the anti-fluoride material layer is formed on the partial inner sidewall of the clean gas channel.

10. The chemical vapor deposition apparatus according to claim 2, characterized in that: the chemical vapor deposition apparatus further comprises an anti-fluoride material pipe which is formed as one piece of an anti-fluoride material, and the clean gas channel is formed in the anti-fluoride material pipe, thereby forming the anti-fluoride material layer in the clean gas channel.

11. The chemical vapor deposition apparatus according to claim 2, characterized in that: the anti-fluoride material layer is selected from a material except metallic oxide.

12. A cooling block of a chemical vapor deposition apparatus, characterized in that: the cooling block comprises:
a block body;
at least one clean gas channel formed in the block body and connected between a process chamber of the chemical vapor deposition apparatus and a remote plasma source; and
an anti-fluoride material layer formed in the clean gas channel.

13. The cooling block according to claim 12, characterized in that: the anti-fluoride material layer is a coating layer.

14. The cooling block according to claim 12, characterized in that: the anti-fluoride material layer is formed by a pipe.

15. The cooling block according to claim 12, characterized in that: the material of the anti-fluoride material layer is Teflon.

16. The cooling block according to claim 12, characterized in that: the anti-fluoride material layer is formed on the whole inner sidewall of the clean gas channel.

17. The cooling block according to claim 12, characterized in that: the anti-fluoride material layer is formed on the partial inner sidewall of the clean gas channel.

18. The cooling block according to claim 12, characterized in that: the anti-fluoride material layer is selected from a material except metallic oxide.
